(19) United States
(12) Patent Application Publication
(10) Pub. No.: US 2014/0284287 A1
(43) Pub. Date: Sep. 25, 2014

(54) MOUNTING APPARATUS FOR DATA STORAGE DEVICE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: SHANG-NONG FAN, Shenzhen (CN); XIU-QUAN HU, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/064,370

(22) Filed: Oct. 28, 2013

(30) Foreign Application Priority Data
Mar. 25, 2013 (CN) 2013100957244

(51) Int. Cl. H05K 7/18; F16M 13/02

(52) U.S. Cl. CPC H05K 7/18; F16M 13/02
USPC 211/4; 248/311.2

(57) ABSTRACT

A mounting apparatus includes a bracket, a handle, and a latching member. The bracket is configured for receiving a data storage device. The handle is rotatably mounted to the bracket. The latching member is secured to the handle and includes an elastically deformable connecting piece and a latching block extending from an end of the connecting piece. The bracket defines a latching slot. A pressed portion extends downwards from the connecting piece. The handle is rotatable relative to the bracket to engage the latching block in the latching hole. The pressed portion is capable of being pressed to elastically deform the connecting piece to disengage the latching block from the latching slot.

### BACKGROUND

1. Technical Field

The present disclosure relates to mounting apparatuses, and particularly to a mounting apparatus for a data storage device.

2. Description of Related Art

Data storage devices are used for storing data in mounting apparatuses, such as computers and servers. Each data storage device is generally mounted in a bracket, and then the bracket is mounted in a computer enclosure by screws, which requires a screw driver to secure the screws to the bracket. Disassembly or reassembly of the data storage devices can be tedious and inconvenient. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a mounting apparatus and a mounting assembly with a data storage device.

FIG. 2 is an assembled, isometric view of the mounting assembly with the data storage device of the mounting apparatus of FIG. 1.

FIG. 3 is an exploded, isometric view of the mounting assembly with the data storage device of the mounting apparatus of FIG. 1.

FIG. 4 is an isometric view of a locking member of the mounting apparatus of FIG. 1.

FIG. 5 is another assembled, isometric view of the mounting assembly with the data storage device, showing a handle in a first position.

FIG. 6 is an assembled, isometric view of the mounting apparatus and the data storage device, with the handle in the first position.

FIG. 7 is an enlarged view of a circled portion VII of FIG. 6.

FIG. 8 is similar to FIG. 6, but viewed from a different aspect.

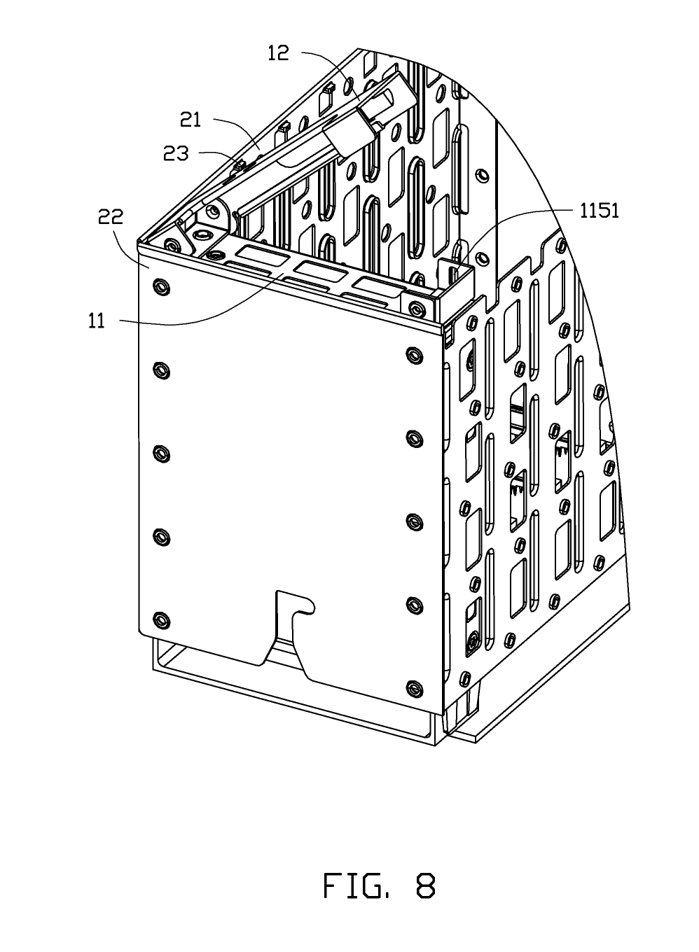

FIG. 9 is another assembled, isometric view of the mounting apparatus and the data storage device, showing the handle in a second position.

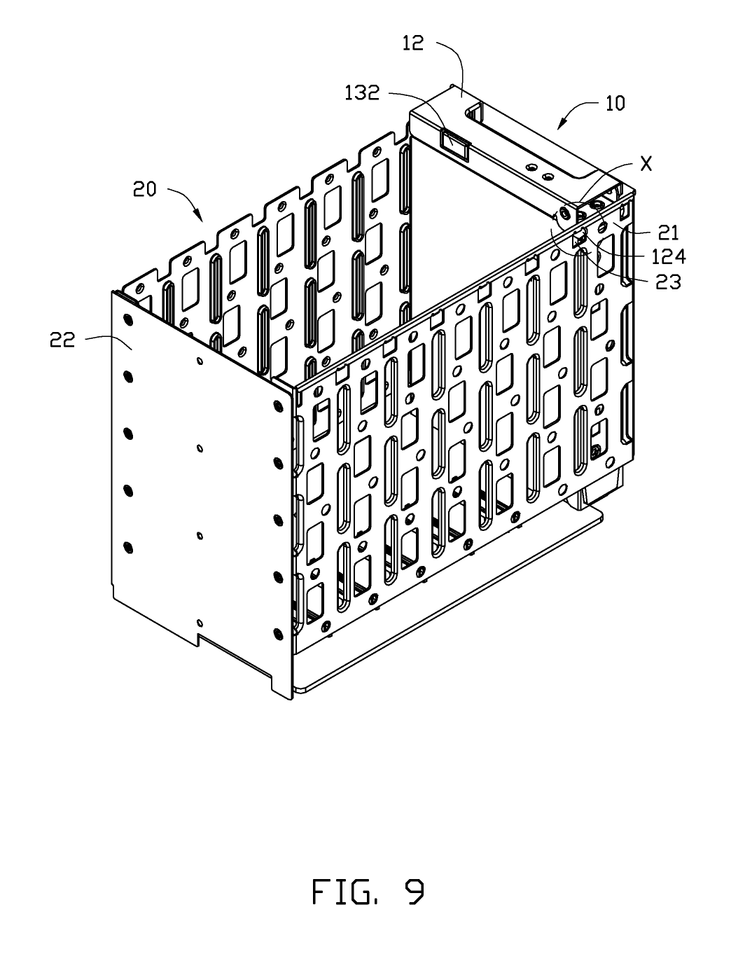

FIG. 10 is an enlarged view of a circled portion X of FIG. 9.

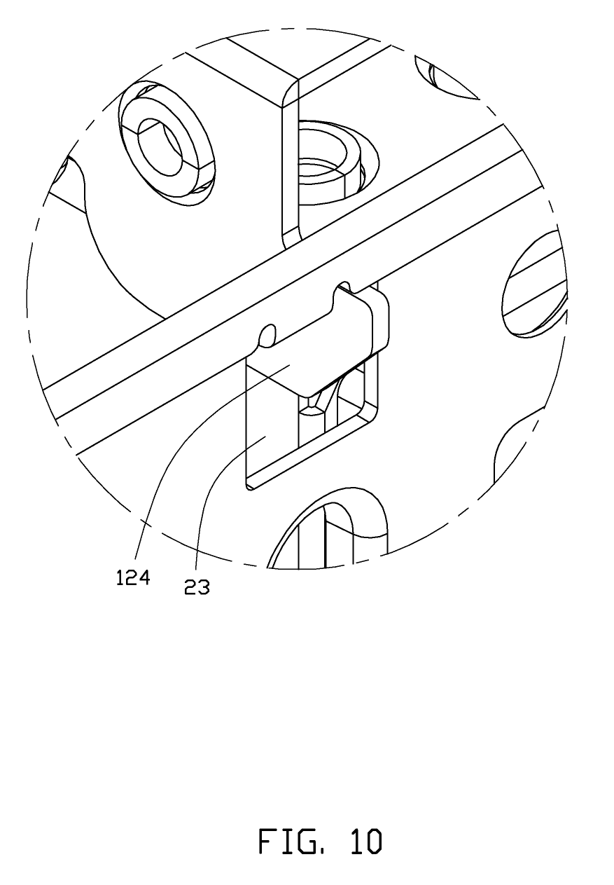

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

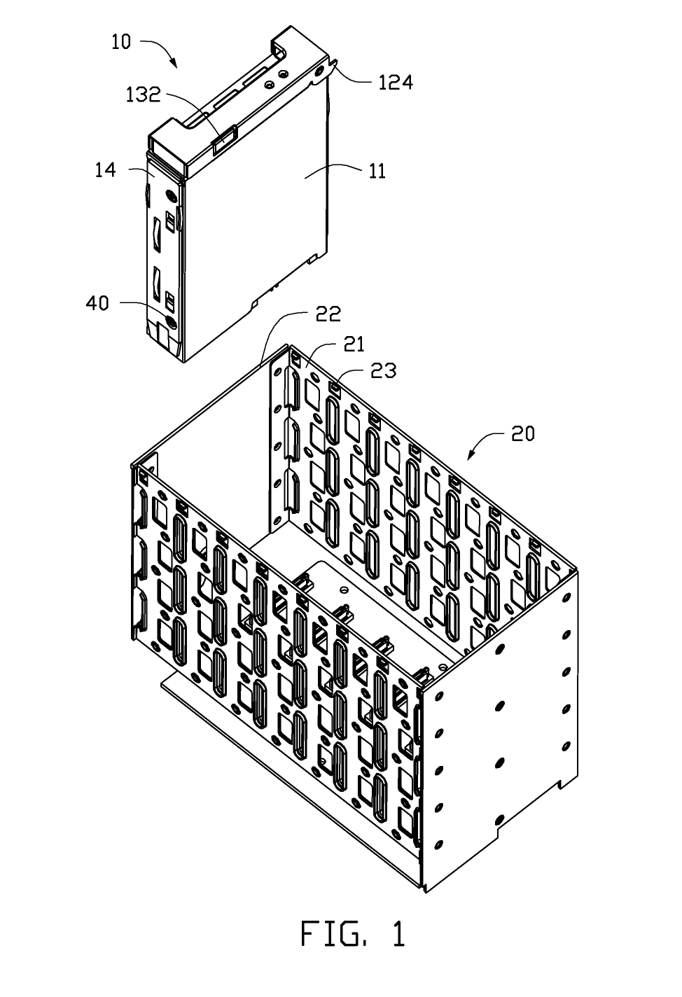

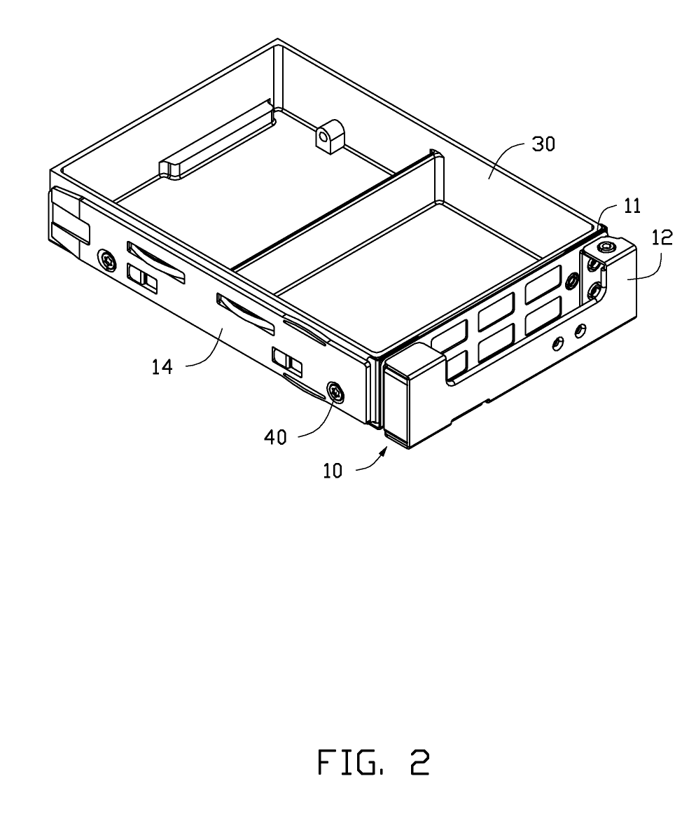

FIGS. 1 and 2 show one embodiment of a mounting apparatus for securing a data storage device 30. The mounting apparatus includes a mounting assembly 10 for receiving the data storage device 30 and a chassis 20 for receiving the mounting assembly 10. In one embodiment, the data storage device 30 is a hard disk drive.

The chassis 20 includes two first side plates 21 and two second side plates 22 connected to the two first side plates 21. In one embodiment, the two first side plates 21 are substantially parallel to each other, and the two second side plates 22 are substantially parallel to each other and perpendicular to each first side plate 21. Each first side plate 21 defines a latching hole 23.

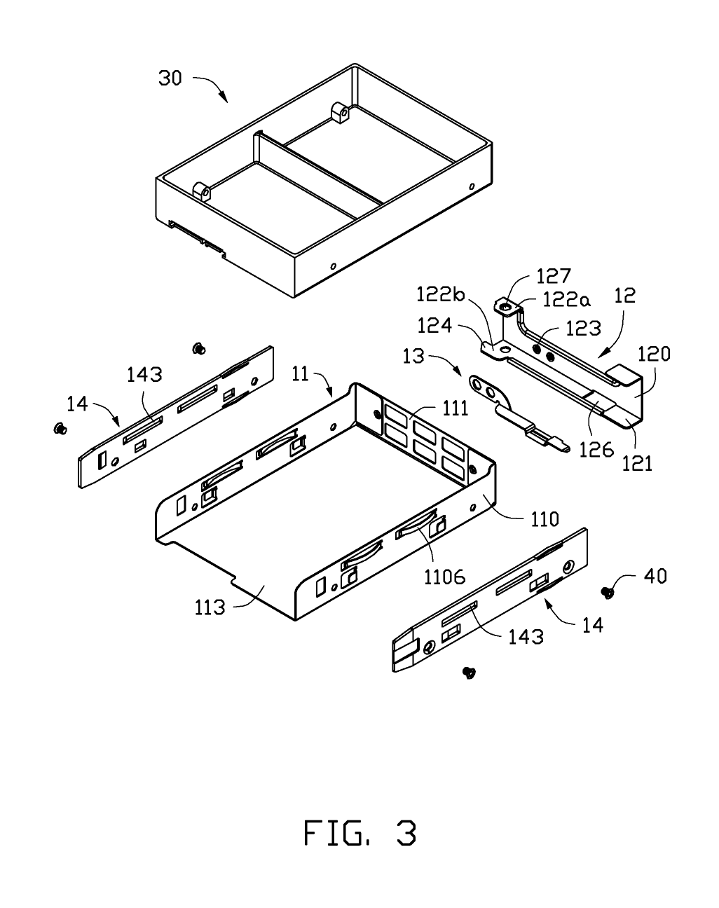

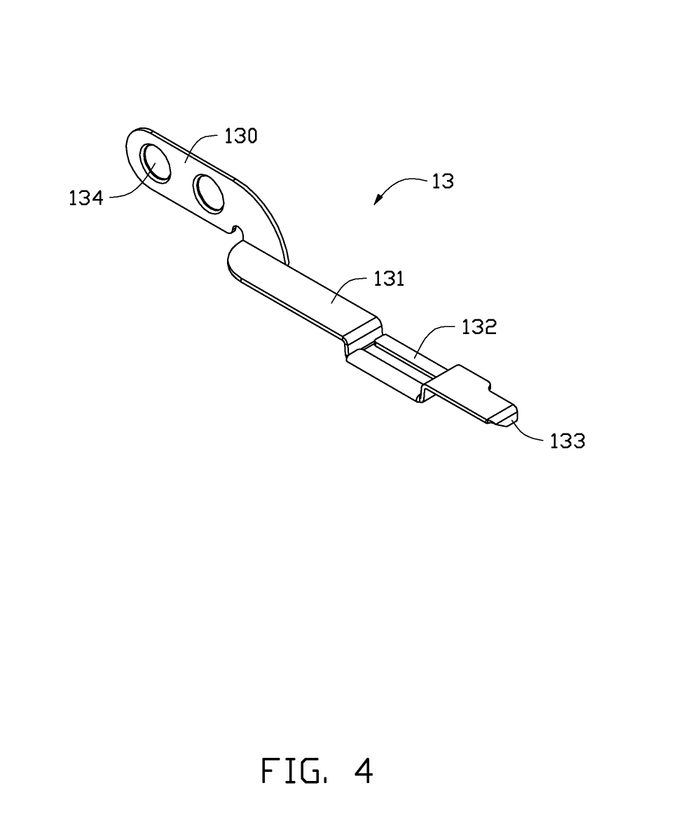

FIGS. 3 and 4 show that the mounting assembly includes a bracket 11, a handle 12, a locking member 13, and two guiding plates 14.

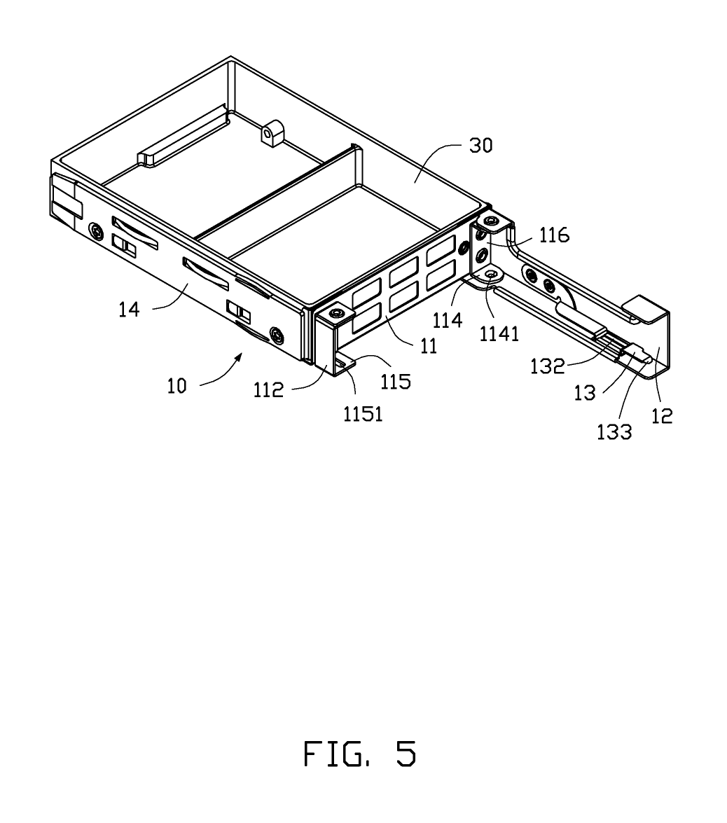

The bracket 11 includes two sidewalls 110, a front wall 111 connected to the two sidewalls 110, and a bottom wall 113 connected to the two sidewalls 110 and the front wall 111. In one embodiment, the bottom wall 113 is substantially perpendicular to the front wall 111 and each sidewall 110, and the front wall 111 is substantially perpendicular to each sidewall 110. Two resilient pieces 1106 extend from each sidewall 110. Each resilient piece 1106 is curved. Referring to FIG. 5, the bracket 11 further includes a first mounting portion 112 and a second mounting portion 116 located on the front wall 11. The first mounting portion 112 includes two opposite first mounting pieces 115 extending in a first direction. One of the two first mounting pieces 115, below the other first mounting piece 115, defines a latching slot 1151. The second mounting portion 116 includes two opposite second mounting pieces 114 extending in a second direction, which is substantially perpendicular to the first direction, and a pivoting post 1141 extending from each second mounting piece 114. In one embodiment, each first mounting piece 115 and each second mounting piece 114 are substantially perpendicular to the front wall 111, and the pivoting post 1141 is substantially parallel to the front wall 111.

The handle 12 includes a body 120 and a flange 121 extending perpendicularly from a bottom edge of the body 120. Two installation posts 123 extend from the body 120. A first pivoting piece 122a extends from the body 120 and a second pivoting piece 122b extends from the flange 121. The first pivoting piece 122a is substantially perpendicular to the body 121 and defines a pivoting hole 127. A latching piece 124 extends from a side of the second pivoting piece 122b of the flange 121 and is coplanar with the second pivoting piece 122b. The flange 121 defines a through hole 126.

The latching member 13 includes a mounting piece 130, a connecting piece 131, a pressed portion 132 from the connecting piece 131, and a latching block 133 extending downwards from a side edge of the connecting piece 131. The mounting piece 130 defines two mounting holes 134. The pressed portion 132 corresponds to the through hole 126 and is substantially “U” shaped. The latching block 133 corresponds to the latching slot 1151.

Each guiding plate 14 defines two openings 143 corresponding to the two resilient pieces 1106.

FIGS. 2-4 show that in assembly of the mounting assembly 10, the mounting piece 130 is secured to the body 120 with the installation posts 123 engaged in the installation holes 134, which secures the latching member 13 to the body 120. The pressed portion 132 extends out of the through hole 126 and is exposed to the handle 12. The pressed portion 132 can be pressed to elastically deform the connecting piece 131 relative to the mounting piece 130. The handle 12 is pivotably mounted to the second mounting portion with the pivoting post 1141 pivotably received in the pivoting hole 127. Each guiding plate 14 is secured to one of the two sidewalls 110 with two locking members 40, such as screws, inserting through the guiding plate 14 and the sidewall 10. The resilient piece 1106 extends out of the opening 143. The data storage device 30 is mounted in the bracket 11. In this position, the handle 12 is located in a first position and is rotatable freely relative to the bracket 11.

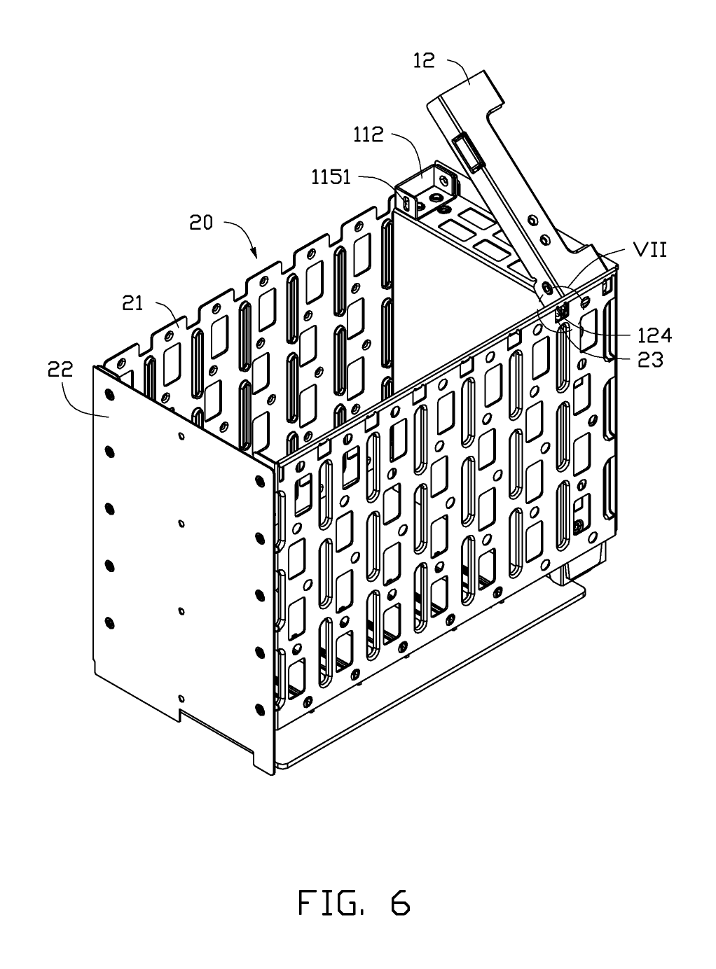

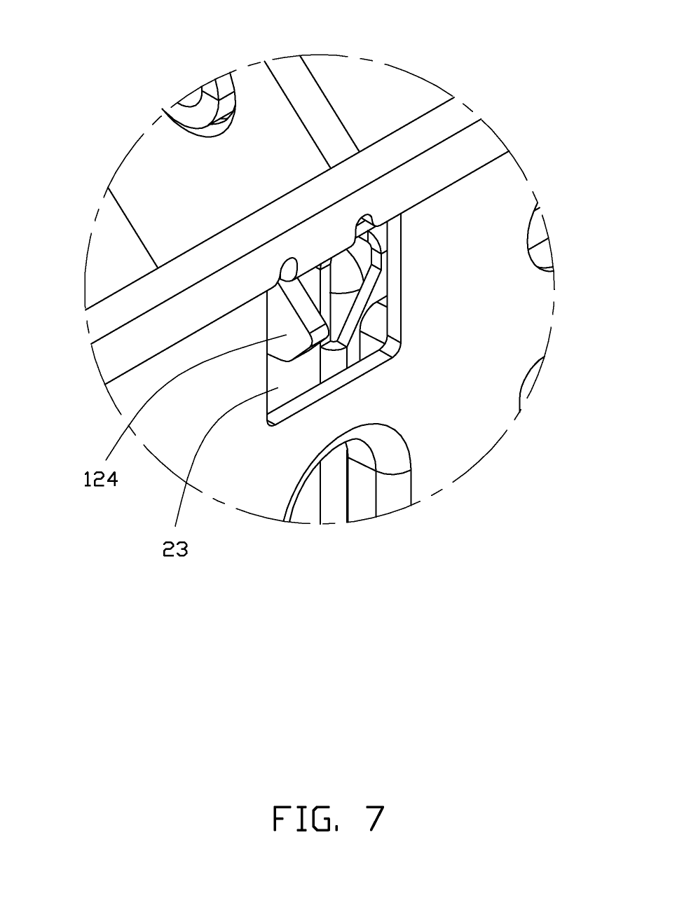

FIGS. 4-7 show that in assembly of the mounting assembly 10 to the chassis 20, the guiding plates 14 are slid into the chassis 20 along the two first side plates 21. The resilient pieces 1106 are elastically deformed to resist the two first side plates 21. The handle 12 is rotated towards the front wall 111 until the latching block 133 is blocked by the first mounting piece 115. The latching piece 124 is inserted in the latching hole 23. The handle 12 is further rotated to elastically deform the connecting piece 131 upwards until the latching block 133 is aligned with the latching slot 1151. The connecting piece 131 rebounds to engage the latching block 133 in the latching slot 1151, to fix the handle 12 to the chassis 11. The latching piece 124 extends out of the latching hole 23. In this position, the handle 12 is located in a second position.

In disassembly of the mounting assembly 10, the pressed portion 132 is pressed to elastically deform the connecting piece 131 to disengage the latching block 133 from the latching slot 1151, and the handle 20 rotated away from the front wall 111 to disengage the latching piece 124 from the latching hole 23. The mounting assembly 10 can then be removed from the chassis 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. A mounting apparatus, comprising:
a bracket configured for receiving a data storage device and comprising a first mounting portion;
a handle rotatably mounted to the bracket; and
a latching member secured to the handle and comprising an elastically deformable connecting piece, a latching block extending from an end of the connecting piece, and a pressed portion extending from the connecting piece;
wherein the first mounting portion defines a latching slot; the handle is rotatable relative to the bracket between a first position and a second position; when the handle is in the first position, the latching block is engaged in the latching slot; when the handle is in the second position, the latching block is disengaged from the latching slot; and when the handle is in the first position, the pressed portion is capable of being pressed to elastically deform the connecting piece to disengage the latching block from the latching slot.

2. The mounting apparatus of claim 1, wherein the handle comprises a body, a flange extending from the body, and a pivoting piece extending from the flange; the latching member is secured to the body; and the pivoting piece is pivotably mounted to the bracket.

3. The mounting apparatus of claim 2, further comprising a chassis, wherein the mounting assembly is received in the chassis; the chassis defines a latching hole; the handle further comprises a latching piece extending from the pivoting piece; when the handle is in the second position, the latching piece is engaged in the latching hole, and when the handle is in the first position, the latching piece is disengaged from the latching hole.

4. The mounting apparatus of claim 2, wherein the pressed portion extends downwards from the connecting piece, the flange defines a through hole, and the pressed portion extends out of the through hole and is exposed out of the handle.

5. The mounting apparatus of claim 2, wherein the bracket further comprises a front wall and a second mounting portion located on the front wall, and the first mounting portion is secured to the front wall; the first mounting portion comprises a first mounting piece, and the latching slot is defined in the first mounting piece; the second mounting portion comprises a second mounting piece and a pivoting post extending from the second mounting piece; and the pivoting piece defines a pivoting hole, and the pivoting post is pivotably received in the pivoting hole.

6. The mounting apparatus of claim 5, wherein the first mounting piece and the second mounting piece are substantially perpendicular to the front wall, and an extending direction of the first mounting piece is substantially perpendicular to an extending direction of the second mounting piece.

7. The mounting apparatus of claim 5, wherein an extending direction of the latching slot is substantially perpendicular to the front wall.

8. The mounting apparatus of claim 5, wherein the pivoting post is substantially parallel to the front wall.

9. The mounting apparatus of claim 5, wherein the first mounting portion and the second mounting portion are located on opposite sides of the front wall.

10. The mounting apparatus of claim 3, further comprising a guiding plate, wherein the bracket further comprises a sidewall and a resilient piece extending from the sidewall, the guiding plate defines an opening, and the resilient piece resists the chassis through the opening.

11. A mounting apparatus, comprising:
a chassis defining a latching hole;
a bracket configured for receiving a data storage device and comprising a first mounting portion; and the bracket being received in the chassis;
a handle rotatably mounted to the bracket and comprising a latching piece; and
a latching member secured to the handle and comprising an elastically deformable connecting piece, a latching block extending from an end of the connecting piece, and a pressed portion extending from the connecting piece;
wherein the first mounting portion defines a latching slot; the handle is rotatable relative to the bracket between a first position and a second position; when the handle is in the first position, the latching block is engaged in the latching slot, and the latching piece is engaged in the latching hole; when the handle is in the second position, the latching block is disengaged from the latching slot, and the latching piece is disengaged from the latching hole; and when the handle is in the first position, the pressed portion is capable of being pressed to elastically deform the connecting piece to disengage the latching block from the latching slot.

12. The mounting apparatus of claim 11, wherein the handle further comprises a body, a flange extending perpendicularly from the body, and a pivoting piece extending from the flange; the latching member is secured to the body; and the pivoting piece is pivotably mounted to the bracket.

13. The mounting apparatus of claim 12, wherein the latching piece extends from an edge of the pivoting piece, and the latching piece is coplanar with the pivoting piece.

14. The mounting apparatus of claim 12, wherein the pressed portion extends downwards from the connecting piece, the flange defines a through hole, and the pressed portion extends out of the through hole and is exposed out of the handle.

15. The mounting apparatus of claim 12, wherein the bracket further comprises a front wall and a second mounting portion located on the front wall, and the first mounting portion is secured to the front wall; the first mounting portion comprises a first mounting piece, and the latching slot is defined in the first mounting piece; the second mounting portion comprises a second mounting piece and a pivoting post extending from the second mounting piece; and the pivoting piece defines a pivoting hole, and the pivoting post is pivotably received in the pivoting hole.

16. The mounting apparatus of claim 15, wherein the first mounting piece and the second mounting piece are substantially perpendicular to the front wall, and an extending direction of the first mounting piece is substantially perpendicular to an extending direction of the second mounting piece.

17. The mounting apparatus of claim 15, wherein an extending direction of the latching slot is substantially perpendicular to the front wall.

18. The mounting apparatus of claim 15, wherein the pivoting post is substantially parallel to the front wall.

19. The mounting apparatus of claim 15, wherein the first mounting portion and the second mounting portion are located on opposite sides of the front wall.

20. The mounting apparatus of claim 11, further comprising a guiding plate, wherein the bracket further comprises a sidewall and a resilient piece extending from the sidewall, the guiding plate defines an opening, and the resilient piece resists the chassis through the opening.
